(19) United States
(12) Patent Application Publication
(10) Pub. No.: US 2014/0077319 A1
(43) Pub. Date: Mar. 20, 2014

(54) MAGNETORESISTIVE EFFECT ELEMENT AND MANUFACTURING METHOD THEREOF

(71) Applicant: KABUSHIKI KAISHA TOSHIBA, Tokyo (JP)

(72) Inventors: Kenji NOMA, Yokohama-shi (JP); Hitoshi KUBOTA, Tsukuba-shi (JP); Kay YAKUSHIJI, Tsukuba-shi (JP)

(73) Assignee: KABUSHIKI KAISHA TOSHIBA, Tokyo (JP)

(21) Appl. No.: 13/802,693

(22) Filed: Mar. 13, 2013

(30) Foreign Application Priority Data
Sep. 18, 2012 (JP) 2012-205010

(51) Int. Cl. H01L 43/02; H01L 43/12

(52) U.S. Cl. CPC H01L 43/02; H01L 43/12
USPC 257/421; 438/3

(57) ABSTRACT

According to one embodiment, a magnetoresistive effect element includes a multilayer film including a transition metal nitride film, an antiferromagnetic film, a first ferromagnetic film, a nonmagnetic film, and a perpendicular magnetic anisotropic film stacked in that order. The first ferromagnetic film has a negative perpendicular magnetic anisotropic constant. Magnetization of the first ferromagnetic film is caused to point in a direction perpendicular to the film surface forcibly by an exchange-coupling magnetic field generated by the antiferromagnetic film.

### CROSS-REFERENCE TO RELATED APPLICATIONS

This application is based upon and claims the benefit of priority from Japanese Patent Application No. 2012-205010, filed Sep. 18, 2012, the entire contents of which are incorporated herein by reference.

### FIELD

Embodiments described herein relate generally to a magnetoresistive effect element and a manufacturing method thereof.

### BACKGROUND

The giant magnetoresistive effect (GMR) in a [ferromagnetic film/nonmagnetic film] n artificial lattice film was presented (in Phys. Rev. Lett., Vol. 61, No. 21, pp. 2472) by A. Fert, P. A. Grunberg, et al., in 1989. After that, International Business Machines Corporation has developed a spin valve magnetoresistive effect film with a multilayer structure of ferromagnetic film/nonmagnetic film/ferromagnetic film/antiferromagnetic film obtained by simplifying an artificial lattice part and adding an antiferromagnetic film. As a result of this development, magnetoresistive effect films have been put to practical use as reproducing head elements for hard disk drives (HDDs).

In addition, a tunneling magnetoresistive effect (TMR) at room temperature verified by T. Miyazaki, et al., in 1995 was found in a structure of ferromagnetic film/aluminum oxide (Al—O) tunnel barrier film/ferromagnetic film. Later, TDK Corporation put this structure to practical use as a multilayer structure of ferromagnetic film/Al—O tunnel barrier film/ferromagnetic film/antiferromagnetic film obtained by adding an antiferromagnetic film (IEEE Trans. Magn., Vol. 38, No. 1, pp. 72). Furthermore, a giant tunnel magnetoresistive effect using a (100) oriented film of magnesium oxide (MgO) as a tunnel barrier film was theoretically predicted by W. H. Butler, et al., in 2001 and verified by S. Yuasa, et al., in 2003. Anelva Corporation (newly named Canon Anelva Corporation) developed a magnetoresistive effect element with a multilayer structure of ferromagnetic film/MgO tunnel barrier film/ferromagnetic film/antiferromagnetic film in 2004. With this development, the giant magnetoresistive effect has been put to practical use.

What has been described above is related to an example of practical use in the field of HDD reproducing heads. An example of putting an element using a magnetoresistive effect film to practical use in another field is a magnetic random access memory (MRAM). In MRAMs developed by Motorola Corporation and mass-produced by Freescale Semiconductor Corporation, it is thought that a magnetic tunnel junction (MTJ) element basically having a multilayer structure of ferromagnetic film/Al—O tunnel barrier film/ferromagnetic film/antiferromagnetic film has been used as an element that stores information.

Magnetoresistive effect films put to practical use in HDD reproducing heads and MRAMs have been used in such a manner that they not only have a multilayer structure of ferromagnetic film/nonmagnetic film/ferromagnetic film but also are always provided with an antiferromagnetic film. Speaking of magnetoresistive effect films in the development of new films, a multilayer-structure film with an antiferromagnetic film is common. Since an exchange-coupling magnetic field generated by an antiferromagnetic film has the effect of fixing the magnetization direction of an adjacent ferromagnetic film almost in a direction, an antiferromagnetic film is regarded as an indispensable element for the stabilization of a reproduced signal from an HDD reproducing head and for a long-term retention of binary data stored in an MRAM.

It is known that MRAMs currently mass-produced by Freescale Semiconductor Corporation (newly named Everspin Technologies) use a magnetic-field writing method in writing information. The magnetic-field writing method is regarded as being unsuitable for speeding up and higher integration because of the following barrier in principle: the write time is long and, if an MRAM is miniaturized, the necessary write current increases, exceeding the capability of a driving transistor. On the other hand, instead of the magnetic-field writing method, the spin transfer writing method using a spin transfer magnetization switching (STS) phenomenon verified in 2000 is applied to the MRAM and it is expected that more speeding up and higher integration of the MRAM than those of the dynamic random access memory (DRAM) will be realized.

Above all, a perpendicular magnetization MTJ element that uses, as a storage element, a ferromagnetic film whose magnetization points in a direction perpendicular to the surface of a multilayer film enables a spin transfer current to have a shorter pulse and be made lower than a conventional MTJ element whose magnetization points in an in-plane direction. Therefore, it is though that the ultimate high-speed, high-integration MRAM can be realized. In the HDD reproducing head, the direction in which a leakage magnetic field from the recording medium is applied is always in the in-plane direction of a magnetoresistive effect film and therefore the magnetization fixing direction of one of the two ferromagnetic films must be in the in-plane direction. Therefore, in the HDD reproducing head, a magnetoresistive effect film including a ferromagnetic film whose magnetization is fixed in a direction perpendicular to the film surface is not used.

At present, with an MRAM using a perpendicular magnetization MTJ element and a spin transfer magnetization switching writing method, in an MTJ element including a multilayer structure of a first ferromagnetic film/a tunnel barrier film/a second ferromagnetic film, the first and second ferromagnetic films are compose of perpendicular magnetic anisotropic films and the coercive force of the first perpendicular magnetic anisotropic film is made greater than that of the second perpendicular magnetic anisotropic film, thereby producing a state where the magnetization direction of the first perpendicular magnetic anisotropic film is fixed. As an example of the perpendicular magnetic anisotropic film, cobalt-platinum (Co—Pt) alloy used for an HDD recording medium and a rare earth-transition metal amorphous alloy (RE-TM), such as terbium-iron-cobalt (Tb—Fe—Co) used for magnetooptical recording, are known. These materials are formed into a film by depositing them on a substrate by, for example, sputtering techniques. With the film as a whole, a perpendicular magnetic anisotropic constant of Ku=1×10⁵ J/m³ or more has been obtained.

Most of the in-plane magnetization MTJ elements currently used for HDD reproducing heads or MRAMs use an antiferromagnetic film to fix magnetization. In the perpendicular magnetization MTJ element, since a demagnetizing field is great when the magnetization of a ferromagnetic film points in a direction perpendicular to the film surface, a sufficient exchange-coupling magnetic field to fix the magnetization of the ferromagnetic film has not be obtained from a currently commonly-known antiferromagnetic film. Therefore, it is necessary to use a perpendicular magnetic anisotropic film as a ferromagnetic film in the present circumstances. However, fixing the magnetization of the perpendicular magnetic anisotropic film in a direction perpendicular to the film surface by the antiferromagnetic film is not only meaningless but also has only a negative effect of making the overall film thickness of the multilayer film greater by the thickness of the antiferromagnetic film. Therefore, it is a common practice that a perpendicular magnetization MTJ element currently developed for an MRAM is composed of only a perpendicular magnetic anisotropic film, not provided with an antiferromagnetic film.

On the other hand, semiconductor memories are required to increase the integration degree by making the storage element size smaller. The limit of the size is determined by the accuracy of microfabrication of an MTJ element. The microfabrication is generally realized by forming a pattern mask on an MTJ element by photolithographic techniques and then removing a mask opening part by ion beam etching (IBE) or reactive ion etching (RIE) techniques. However, since a ferromagnetic film used for an MTJ element has a low material selection ratio in RIE, an ordinary rectangular cross-sectional shape cannot be obtained in a semiconductor process, resulting in a tapered shape with the cross section inclined at 45 to 60 degrees to the film surface. Therefore, in principle, the overall film thickness of an MTJ element must be made as thin as about the storage element size.

For example, to form an 8F² (F being minimum feature size) layout array with a storage element size of 60 nm and a cell interval of 60 nm by microfabrication techniques, the overall film thickness of an MTJ element must be made about 52 nm or less under processing conditions of a taper angle of 60 degrees. This is because processing a film thicker than this by microfabrication techniques permits bits adjacent to each other at the bottom of the tapered shape to connect with each other. To put it the other way around, to increase the integration degree of the MRAM, the MTJ element must be made thinner. If the taper angle gets closer to 90 degrees, there is no limit to the film thickness of the MTJ element. At present, however, a method of processing a dense pattern in that way is unknown.

As the perpendicular magnetic anisotropic film is made thinner to cope with the process limitation, a demagnetizing field increases in inverse proportion to the film thickness, whereas an anisotropic magnetic field decreases. Therefore, eventually the thin-film formation limit of a perpendicular magnetic anisotropic film will be reached. Generally, when a film thickness of about 40 nm or less in the aforementioned alloy series or a film thickness of about 25 nm or less in the RE-TM series has been reached, the perpendicular magnetic anisotropy begins to get lower, with the result that the magnetization direction begins to include a in-plane component at an average operational temperature of a semiconductor memory, for example, at a temperature of about 85° C. That is, the magnetization cannot be fixed in a direction. Even if a ferromagnetic film whose magnetization is not fixed is thinner than this, it can perform a memory operation, provided that its perpendicular magnetic anisotropic constant is in a positive range. Even so, a film thickness of about 5 nm in the alloy series or a film thickness of about 2 nm in the RE-TM series is a limit.

In addition, since a leakage magnetic field from the perpendicular magnetic anisotropic film whose magnetization is fixed is proportional to the film thickness, the magnitude of the leakage magnetic field cannot be made equal to or lower than the thin-film formation limit. On the other hand, when a third ferromagnetic film for decreasing a leakage magnetic field from a magnetization fixed layer is added, since the third ferromagnetic film also has a thin-film formation limit, an overall film thickness of 80 nm or more in the alloy series or an overall film thickness of 50 nm or more in the RE-TM series is generally needed. This means that an MRAM using a perpendicular magnetization MTJ element cannot deal with high integration of a size equal to or smaller than this, which is fatal to the semiconductor memory.

As a means for decreasing a leakage magnetic field, the use of a material with a low saturated magnetization as a perpendicular magnetic anisotropic film whose magnetization is fixed has been under consideration. However, a complete solution has not been figured out at present because of the following side-effects: the magnetoresistive effect gets smaller and the heat resistance deteriorates further.

### BRIEF DESCRIPTION OF THE DRAWINGS

FIG. 1 is a sectional view showing a configuration of a first exchange-coupling multilayer film;

FIG. 2 is a magnetization curve of a multilayer film according to a comparative example;

FIG. 3 is a magnetization curve of an exchange-coupling multilayer film according to a first embodiment;

FIG. 4 is a magnetization curve of an exchange-coupling multilayer film according to a second embodiment;

FIG. 5 is a sectional view showing a configuration of a second exchange-coupling multilayer film;

FIG. 6 is a sectional view showing a configuration of an inversely stacked layer MTJ element;

FIG. 7 is a sectional view showing a configuration of an inversely stacked layer MTJ element with a shift adjusting layer;

FIG. 8 is a sectional view showing a configuration of an inversely stacked layer MTJ element according to a modification;

FIG. 9 is a sectional view showing a configuration of an inversely stacked layer MTJ element according to a modification;

FIG. 10 is a sectional view showing a configuration of a normally stacked layer MTJ element;

FIG. 11 is a sectional view showing a configuration of a normally stacked layer MTJ element with a shift adjusting layer;

FIG. 12 is a sectional view showing a configuration of a normally stacked layer MTJ element according to a modification;

FIG. 13 is a sectional view showing a configuration of a normally stacked layer MTJ element according to a modification;

FIG. 14 is a sectional view showing a configuration of an MRAM;

FIG. 15 is a schematic diagram of a magnetizing apparatus; and

FIG. 16 is a schematic diagram showing another configuration of the magnetizing apparatus.

### DETAILED DESCRIPTION

In general, according to one embodiment, there is provided a magnetoresistive effect element comprising:

a multilayer film including a transition metal nitride film, an antiferromagnetic film, a first ferromagnetic film, a nonmagnetic film, and a perpendicular magnetic anisotropic film stacked in that order,

wherein the first ferromagnetic film has a negative perpendicular magnetic anisotropic constant, and

magnetization of the first ferromagnetic film is caused to point in a direction perpendicular to the film surface forcibly by an exchange-coupling magnetic field generated by the antiferromagnetic film.

Hereinafter, embodiments will be explained with reference to the accompanying drawings. It should be noted that the drawings are schematic or conceptual and that the dimensions and ratio in each drawing are not necessarily the same as the actual ones. When the same part is shown between drawings, the relationship between dimensions and between ratios may be shown differently between drawings. Embodiments illustrate apparatuses and methods for embodying the technical idea of the invention. The shape, structure, and arrangement of component parts do not limit the technical idea of the invention. In the explanation below, elements having the same function and configuration are indicated by the same reference numbers. A repeated explanation will be given only when needed.

Hereinafter, the details of embodiments will be described in stages by dividing the contents into the following three forms: [a]: an exchange-coupling multilayer film, [b]: a magnetoresistive effect element (magnetic tunnel junction (MTJ) element) using [a], [c]: an MRAM using [b].

[a] Exchange—Coupling Multilayer Film

There are two types of exchange-coupling multilayer films: [a-1] one (a first exchange-coupling multilayer film) is obtained by stacking at least a transition metal nitride film, a manganese-based antiferromagnetic film, and a ferromagnetic film whose magnetization direction is fixed one on top of another in that order and [a-2] the other (a second exchange-coupling multilayer film) is obtained by stacking at least a transition metal ferromagnetic nitride film whose magnetization direction is fixed and a manganese-based antiferromagnetic film one on top of another in that order. Both have the same principle of generating an exchange-coupling magnetic field in the vertical direction and therefore will also be described below.

[a-1] First Exchange—Coupling Multilayer Film

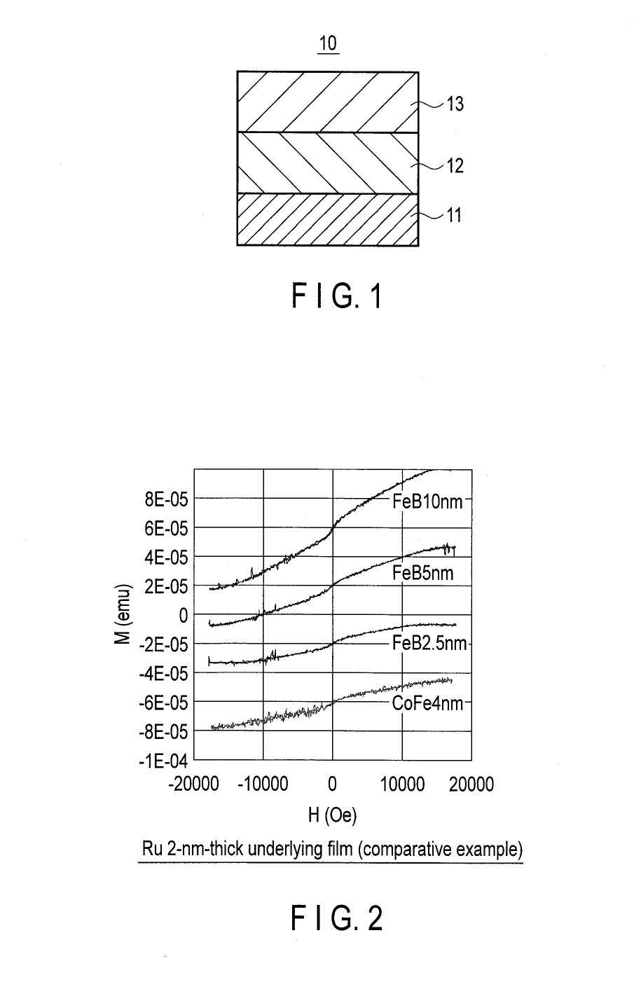

FIG. 1 is a sectional view showing a configuration of a first exchange-coupling multilayer film 10. The exchange-coupling multilayer film 10 includes a multilayer structure obtained by stacking at least a transition metal nitride film 11, a manganese-based antiferromagnetic film 12, and a ferromagnetic film 13 whose magnetization direction is fixed one on top of another in that order. In this case, the transition metal nitride film 11 and manganese-based antiferromagnetic film 12 must be adjacent to each other and stacked in that order. The transition metal nitride film 11 may have a nontransition metal film or a non-nitride film located directly under it as an underlying film.

The ferromagnetic film 13 whose magnetization direction is fixed may be a single-layer ferromagnetic film or a multilayer film composed of a plurality of ferromagnetic films stacked one on top of another or of a plurality of ferromagnetic films and nonmagnetic films stacked one on top of another. The ferromagnetic film 13 is limited to such a film as has a negative perpendicular magnetic anisotropic constant in terms of the entire ferromagnetic film and functions as an in-plane magnetization film whose magnetization points in an in-plane direction when being used alone.

The transition metal nitride film 11 includes alloy nitride any one selected from a group consisting of titanium nitride (Ti—N), vanadium nitride (V—N), chromium nitride (Cr—N), manganese nitride (Nn—N), iron nitride (Fe—N), cobalt nitride (Co—N), copper nitride (Cu—N), ruthenium nitride (Ru—N), and tungsten nitride (W—N), or alloy nitride comprising two or more selected from the group. The enumerated transition metal nitrides are characterized in that (1) they are cubic or tetragonal systems and many of them have an NaCl structure, (2) the atomic radius of transition metal is larger than that of nitrogen, and (3) the lattice constant of crystal (lattice constant in a shorter direction in the case of tetragonal crystal) is in the range of 0.379 to 0.422 nm.

The reason for this is that, since it is at an NaCl (001) plane that an NaCl structure composed of large-atomic-radius elements and small-atomic-radius elements has the largest sum total of the atomic area densities, when an attempt is made to grow a crystal two-dimensionally by a thin-film formation method, such as sputtering techniques, the property of the NaCl (001) plane being apt to grow a parallel crystal at the film surface is needed. This property depends on a crystal structure, regardless of elements, and therefore the property remains unchanged even in a nitride including two of more of the aforementioned transition metals. Therefore, in the transition metal nitride film 11, a (001) crystal plane has a preferred orientation almost in parallel with the film surface.

Although non-nitride includes a material with a cubic or tetragonal crystal structure, only oxide and sulfide enable a (001) plane oriented film to be obtained by a normal thin-film formation method. These are insulating materials and therefore unsuitable for use in the embodiment. In addition, nitride excluding transition metal, such as boron nitride or aluminum nitride, does not have an NaCl structure. Sodium nitride does not have a 1:1 composition and therefore does not have the above property.

As described above, when an antiferromagnetic film 12 has been stacked on the (001)-plane-oriented transition metal nitride film 11, the antiferromagnetic film 12 grows heteroepitaxially with a (001) plane orientation because the lattice constants of both films are very close to each other.

The manganese-based antiferromagnetic film 12 includes any one alloy selected from a group consisting of nickel-manganese (Ni—Mn), palladium-manganese (Pd—Mn), platinum-manganese (Pt—Mn), iridium-manganese (Ir—Mn), rhodium-manganese (Rh—Mn), and ruthenium-manganese (Ru—Mn), or an alloy comprising two or more selected from the group. The enumerated manganese-based antiferromagnetic film 12 includes about 40 to 80 at % (atomic percentage) of manganese (Mn). The manganese-based antiferromagnetic film 12 has a structure where manganese (Mn) is located at a lattice point of a face-centered cubic (fcc) lattice or a face-centered tetragonal (fct) lattice or a metallic element, such as nickel (Ni), palladium (Pd), platinum (Pt), iridium (Ir), rhodium (Rh), or ruthenium (Ru), appears at the lattice point. The lattice constant of the crystal is in the range of 0.375 to 0.407 nm. described above, as for the manganese-based antiferromagnetic film 12, a material whose lattice constant of the crystal is close to that of the transition metal nitride film 11 is selected.

It is known that, in these antiferromagnetic films, the magnetic moment of an Mn atom becomes the largest along a <100> axis of the crystal. Therefore, in the (001)-plane-oriented antiferromagnetic film 12, the percentage of the <100> axis component in a direction perpendicular to the film surface is much larger than that of <110> or <111> axis component, enabling the sum total of the exchange-coupling magnetic field to be made larger effectively. In the case of the (011) or (111) plane orientation, there is no axis component preferentially pointing in a direction perpendicular to the film surface and therefore the magnetic moment is dispersed in an in-plane direction, making smaller the sum total of the exchange-coupling magnetic field in a direction perpendicular to the film surface.

Generally, a spin valve film with in-plane magnetization or a manganese-based antiferromagnetic film used for an MTJ element has a (111) plane orientation. The reason for this is that, if the film is caused to have a (000) plane orientation, an exchange-coupling magnetic field in a direction perpendicular to the film surface becomes stronger, having an adverse effect on the fixation of magnetization of the ferromagnetic film in an in-plane direction. Even if an attempt is made to cause the magnetization of the ferromagnetic film to point in a direction perpendicular to the film surface forcibly by in-magnetic-field heat treatment by stacking a (111)-plane-oriented manganese-based antiferromagnetic film and an ferromagnetic film one on top of the other, such a strong exchange-coupling magnetic field as can alleviate the demagnetizing field of the ferromagnetic film cannot be generated, with the result that the magnetization of the ferromagnetic film points in the in-plane direction. Therefore, the (111)-plane-oriented manganese-based antiferromagnetic film is not suitable for the object of the embodiment, whereas a (001)-plane-oriented one can generate so strong a exchange coupling that can fix magnetization in a direction perpendicular to the film surface.

The ferromagnetic film 13 whose magnetization direction is fixed is basically required to use neither a specific material nor a specific crystal structure and therefore can use a widely used material, such as nickel-iron (Ni—Fe), cobalt (Co), cobalt-iron (Co—Fe), or cobalt-iron-boron (Co—Fe—B). As for an MTJ element described later, a Co—Fe—B film compatible with an MgO tunnel barrier film is used.

Whether such an exchange-coupling multilayer film 10 can be actually realized is shown using data. An experimental method is as follows. First, a silicon substrate is introduced into a vacuum chamber. Then, the surface of the substrate is cleaned by ion bombardment or the like. Next, a metal target of tantalum (Ta) is sputtered with gaseous argon, thereby depositing a Ta film to a thickness of about 5 nm on the silicon substrate. The Ta film plays a passivation role to prevent the single crystal of the silicon substrate from influencing an upper layer.

Next, a transition metal nitride film 11 is deposited on the Ta film. To compare the effects of nitride films, the following three types of specimens are produced: (1) an about 2-nm-thick ruthenium (Ru) film, (2) a 3-nm-thick Ru—N film, and (3) a 3-nm-thick Cu—N film. The Ru film in (1), which is a practical MTJ element, is generally used as a substrate for a manganese-based antiferromagnetic film. It is known that a manganese-based antiferromagnetic film deposited on the Ru film almost always has a (111) plane orientation. The Ru—N film in (2) or Cu—N film in (3) is formed by sputtering a ruthenium (Ru) or copper (Cu) target with a gaseous mixture of argon (90 vol %) and nitrogen (10 vol %) this time, that is, by the reactive sputtering of a metal target, instead of discharging gaseous argon and sputtering a metal target when another non-nitride film is deposited.

Next, on the transition metal nitride film 11, an Ir—Mn film is deposited to a thickness of about 7 nm as an antiferromagnetic film 12 by sputtering a composition alloy target of Ir (20 at %) and Mn (80 at %) with gaseous argon. The Ir—Mn film is in a composition range that allows the magnetic moment of an Mn atom to become the largest in a <100> axis direction. When a film is formed by raising the temperature of the silicon substrate to about 200 to 350° C. when the Ir—Mn film is deposited, the exchange-coupling magnetic field becomes several times greater than when the film is formed at room temperature. In this case, too, the magnetic moment of the Mn atom becomes the largest in a <100> axis direction and therefore the formation of a film at higher temperatures enables magnetization to be fixed stronger in a direction perpendicular to the film surface.

Next, on the antiferromagnetic film 12, an iron-boron (Fe—B) film is deposited to a thickness of about 10 nm as a ferromagnetic film 13 by sputtering a composition alloy target of Fe (80 at %) and B (20 at %) with gaseous argon. The Fe—B film has a saturated magnetization of about 1.5 tesla after heat treatment and therefore is suitable for the generation of a sufficiently strong exchange-coupling magnetic field in a direction perpendicular to the film surface by the method of the embodiment. Then, the Ru target is sputtered with gaseous argon, thereby depositing an Ru film to a thickness of about 0.85 nm. This is a general material stacked on a magnetization fixed layer in an actual MTJ element.

Next, after a composition alloy target of Cr (80 at %) and B (20 at %) is sputtered with gaseous argon, thereby depositing a nonmagnetic chrome-boron (Cr—B) film to a thickness of about 2.5 nm, and a Ta target is sputtered with gaseous argon, thereby depositing a Ta film to a thickness of about 5 nm, and then the specimen is taken out from the vacuum chamber into the air. The Cr—B film and Ta film are protective films for preventing the Fe—B film from being oxidized when the film has been taken out into the air or in a subsequent heat treatment process.

In the exchange-coupling multilayer film as described above, the state of the interface between the antiferromagnetic film 12 and the ferromagnetic film 13 whose magnetization is fixed is always important. Particularly when a part of the interface has been oxidized, iridium is hardly oxidized, Mn is oxidized, Mn—O can generate only a much smaller exchange-coupling magnetic field than Ir—Mn, and Fe—O has a phase that presents antiferromagnetism and might produce a magnetic domain in the Fe—B film, with the result that the chances are high exchange coupling will be impeded. Therefore, it is absolutely imperative that such an exchange-coupling multilayer film should be deposited continuously in a vacuum so as to prevent the film from being oxidized by oxygen or water in the air.

Actually, various targets, such as five targets, Ta, Ru, Ir (20 at %)-Mn (80 at %), Fe (80 at %)-B (20 at %), and Cr (80 at %)-B (20 at %) in the above example, are installed in a single vacuum chamber. That is, a five-target chamber is used. Alternatively, a sputtering apparatus has been put to practical use where chambers in which one or two targets have been installed are directly connected with a vacuum transfer chamber and targets are transported by a robot. Use of this type of apparatuses enables exchange-coupling multilayer films to be formed with good reproducibility.

The silicon substrate on which a multilayer film has been formed is introduced into a vacuum heat-treating furnace capable of applying a 1-tesla direct-current magnetic field continuously in a direction perpendicular to the film surface. With the substrate being heated at 270° C. with a heater, the substrate is subjected to an in-magnetic-field heat treatment for about two hours and then taken out into the air after having cooled to room temperature. In the heat treatment condition, the applied magnetic field is set at 1 tesla because it has to be larger than the demagnetizing field of a 10-nm-thick Fe—B film. Any applied magnetic field may be used, provided that it is larger than 1 tesla. The heating temperature and heating time are set at 270° C. for two hours as conditions for promoting the regularization of the magnetic moment of the Ir—Mn film. If there is such a problem as a low heat resistance of another part, they may be set at, for example, 250° C. for six hours. The heating temperature may be set higher than that. For example, to promote the crystallization of the Fe—B film, they may be set at 300° C. for one hour.

An apparatus that performs such an in-magnetic-field heat treatment has already been put to practical use. Methods of applying a magnetic field are of two types: one using a permanent magnet and the other using an electromagnet. The method using an electromagnet is available in two types: one using a normal conducting coil to generate a magnetic field and the other using a superconducting coil. At present, when a magnetic field is applied in a direction perpendicular to the surface of a 12-inch silicon substrate generally used in manufacturing memories, up to 1 tesla can be applied with a permanent magnet, up to 1.5 tesla with a normal conducting coil, and up to 5 tesla with a superconducting coil. To perform exchange coupling reliably, it is most desirable to use a superconducting-coil in-magnetic-field heat-treating furnace capable of applying up to 5 tesla at which a demagnetizing field can be cancelled completely.

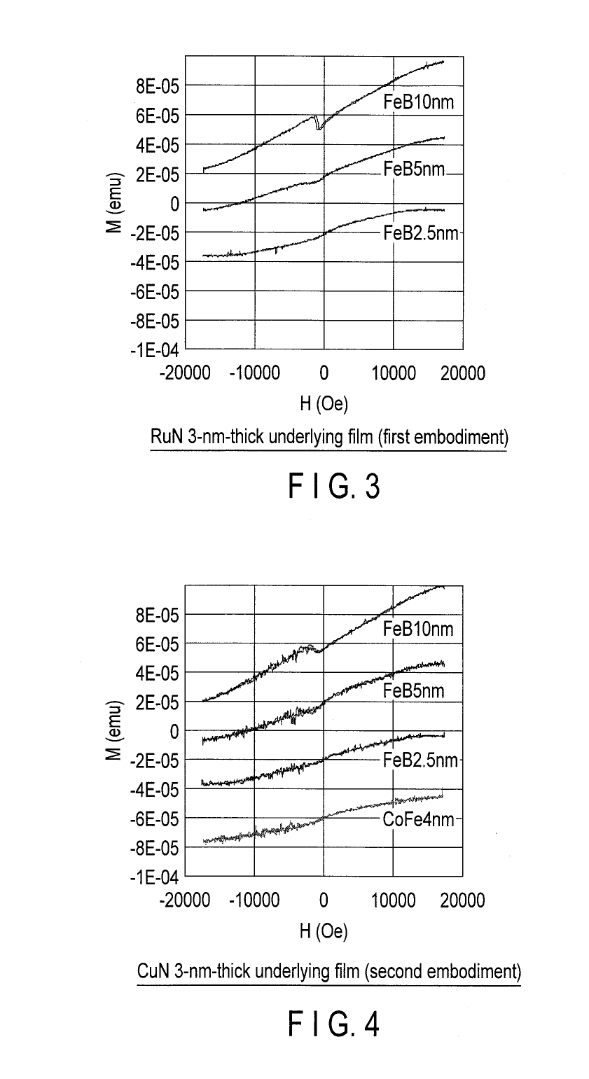

To evaluate a magnetic characteristic, a sweep magnetic field of −1.8 to +1.8 tesla was applied in a direction perpendicular to the film surface of an Fe—B film using a general vibrating sample magnetometer (VSM) and a change in the magnetization of the Fe—B film was plotted as a magnetization curve (M-H curve). FIG. 2 shows magnetization curves of multilayer films (in a comparative example) when an about 2-nm-thick Ru film was used in place of the transition metal nitride film 11. FIG. 3 shows magnetization curves of exchange-coupling multilayer films (in a first embodiment) when a 3-nm-thick Ru—N film was used in place of the transition metal nitride film 11. FIG. 4 shows magnetization curves of exchange-coupling multilayer films (in a second embodiment) when a 3-nm-thick Cu—N film was used in place of the transition metal nitride film 11. In FIG. 2 to FIG. 4, the horizontal axis represents an applied magnetic field H (Oe) and the vertical axis represents the magnetic moment M (emu) in a direction perpendicular to the film surface. FIG. 2 to FIG. 4 also show curves obtained by changing the thickness of the Fe—B film and magnetization curves obtained when the Fe—B film was replaced with a Co—Fe film.

In a comparative example (Ru underlying film) of FIG. 2, a magnetization component in a direction perpendicular to the film surface hardly appears. When a magnetic field has been applied to this film in an in-plane direction and then measured, an M-H hysteresis loop appears, provided that a shift caused by an exchange-coupling magnetic field is zero.

In contrast, in the first embodiment (Ru—N underlying film) of FIG. 3, since a hysteresis loop has appeared in the measurement in a direction perpendicular to the film surface and the center of an M-H loop has shifted to an applied magnetic field of about 0.11 tesla, it is seen that an exchange-coupling magnetic field of about 0.11 tesla has been generated in a direction perpendicular to the film surface. In contrast to the M-M curve in the comparative example of FIG. 2 that presents the behavior of a typical in-plane magnetization film, it is seen that the M-H curve of FIG. 3 presents the behavior of a perpendicular magnetic anisotropic film where the magnetization of the Fe—B film rotates in parallel with a direction in which the magnetic field is applied. Similarly in the second embodiment (Cu—N underlying film) of FIG. 4, a hysteresis loop has appeared at an applied magnetic field of about 0.11 tesla.

When an Ir—Mn film has deposited on the Ru—N film or Cu—N film, that the preferred orientation plane of the Ir—Mn crystal is a (001) plane is a chief factor that enables the magnetization of the Fe—B film to be fixed in a direction perpendicular to the film surface in FIGS. 3 and 4. Since this is a phenomenon resulting from the crystal structure of the Ru—N film or Cu—N film, it is conceivable that a similar result is obtained in a similar crystal structure, that is, a cubic or tetragonal system, mainly in other transition metal nitride films having an NaCl structure.

On the other hand, the reason why the magnetization of the Fe—B film has not been fixed in a direction perpendicular to the film surface in FIG. 2 is that Ru is normally apt to grow in a crystal structure of a hexagonal close-packed structure (hcp) and that the preferred orientation plane of the Ru crystal is a (0001) plane and, when an Ir—Mn film is deposited on the (0001) plane, the Ir—Mn film is considered to grow heteroepitaxially in a (111) plane orientation less lattice-mismatched with the Ru (0001) plane. In this case, since a <100> axis where an exchange-coupling magnetic field is the strongest disperses in a cone shape in a direction inclined at about 54° from a direction perpendicular to the film surface, an exchange-coupling magnetic field from 60% or less of the (000) plane-oriented Ir—Mn film can be generated in principle in a direction perpendicular to the film surface. This magnitude is much less than that of the demagnetizing field of the Fe—B film and therefore it is conceivable that the magnetization has not been fixed in a direction perpendicular to the film surface.

An exchange-coupling magnetic field of 0.11 tesla at a 10-nm-thick Fe—B film is converted into exchange-coupling energy: an exchange-coupling magnetic field of 0.11 tesla×a saturated magnetization of 1.5 tesla×a film thickness of 10 nm=0.0165 J/m². This is almost equivalent to the amount of exchange-coupling energy when an Ir—Mn film is caused to have a (111) plane orientation and an exchange-coupling magnetic field is generated in an in-plane direction. To fix the magnetization of the ferromagnetic film 13 forcibly in a vertical direction even when the ferromagnetic film 13 gets thicker or the magnetization of the ferromagnetic film 13 gets stronger, it is desirable that the exchange-coupling energy of the component in a direction perpendicular to the film surface of the exchange-coupling magnetic field should be 0.015 J/m² or more.

A 10-nm-thick Fe—B film has been shown as an example. It is known that an exchange-coupling magnetic field gets stronger in reverse proportion to the thickness of a ferromagnetic film. Therefore, when the magnitude of a direct-current magnetic field applied in a direction perpendicular to the film surface in the in-magnetic-field heat treatment is greater than that of a demagnetizing field, even if the ferromagnetic film 13 gets thinner than 10 nm and the demagnetizing field increases, the magnetization of the ferromagnetic film 13 can be fixed by this method with no problem.

In the embodiment, “the magnetization of the ferromagnetic film points in a direction perpendicular to the film surface” means not only a case where the magnetization of the ferromagnetic film points completely in a direction perpendicular to the film surface but also a case where the magnetization as a whole points in a direction perpendicular to the film surface even if the magnetization partially does not point in a direction perpendicular to the film surface. For example, it is all right if the magnetization equivalent to 90% or more of the total magnetic moment of the ferromagnetic film is caused to point in a direction perpendicular to the film surface.

In addition, films using materials and compositions other than those shown in the experimental example can be used in the same method. A material other than silicon may be used as a substrate on which a film is to be deposited. The transition metal nitride film 11 may be made of not only a Ru—N film but also Ti—N, V—N, Cr—N, Mn—N, Fe—N, Co—N, Cu—N, W—N, or a compound of these. The antiferromagnetic film 12 may be made of not only an Ir—Mn film but also Ni—Mn, Pd—Mn, Pt—Mn, Ph—Mn, Ru—Mn, or an alloy of these. The ferromagnetic film 13 composed of a film with any composition can fix the magnetization in a direction perpendicular to the film surface by the above method, provided that the material of the film includes at least one of cobalt (Co), iron (Fe), and nickel (Ni) and presents ferromagnetism.

As for the film thickness of each layer, a film thicker or thinner than that shown in the example may be formed. Even when a part of or all of the layers differ in layer thickness, if the transition metal nitride film 11 has a (001) plane orientation and the antiferromagnetic film 12 deposited on the transition metal nitride film 11 has a (001) plane orientation, it goes without saying that the requirements of the embodiment are fulfilled.

As for a method of forming the transition metal nitride film 11, sputtering may be performed using a gaseous mixture of argon and nitrogen with a different mixing ratio. The gaseous mixture may be, for example, argon-ammonia. A nitride target may be sputtered by gaseous argon alone or a gaseous mixture of argon and nitrogen. As for these sputtering methods, the best combination of them may be selected, depending on the solid state properties of a transition metal nitride film 11 to be formed, the reproducibility of film formation, the internal structure of the vacuum chamber, or the like. As for targets, an alloy target has been shown as an example in the case of the Ir—Mn film. The same result is obtained by a method of performing sputtering by using a composite target where an Ir strip is placed on an Mn target or by a co-sputtering method of sputtering an Mn target and an Ir target at the same time.

Furthermore, while in the embodiment, the method of forming the ferromagnetic film 13 or antiferromagnetic film has been explained using a general sputtering method, the same effect is obtained by another film formation method, for example, a vacuum vapor deposition method, a molecular beam epitaxy (MBE) method, a chemical vapor deposition (CVD) method, a liquid phase growth method, or a laser ablation method, provided that a film formation method enables the transition metal nitride film 11 to have a similar crystalline orientation. In addition, with an apparatus that forms films successively in a vacuum, even when a film is formed by a sputtering method for a layer and another film is formed by a vacuum vapor deposition method for another layer, thereby forming a multilayer film, there is no problem.

[a-2] Second Exchange—Coupling Multilayer Film

FIG. 5 is a sectional view showing a configuration of a second exchange-coupling multilayer film 20. The exchange-coupling multilayer film 20 includes a multilayer structure obtained by stacking at least a transition metal ferromagnetic nitride film 21 whose magnetization direction is fixed and a manganese-based antiferromagnetic film 22 one on top of the other in that order. In other words, it would be safe to say that the transition metal ferromagnetic nitride film 21 plays the roles of both the transition metal nitride film 11 and ferromagnetic film 13 in the first exchange-coupling multilayer film 10 in [a-1].

The transition metal ferromagnetic nitride film 21 includes any one selected from a group consisting of Mn—N, Fe—N, and Co—N, or alloy nitride comprising two or more selected from the group. The enumerated transition metal magnetic nitrides are characterized in that (1) they are cubic or tetragonal systems and many of them have an NaCl structure, (2) the atomic radius of transition metal is larger than that of nitrogen, and (3) the lattice constant of crystal (lattice constant in a shorter direction in the case of tetragonal crystal) is in the range of 0.379 to 0.387 nm. In addition, in the transition metal ferromagnetic nitride film 21, a (001) crystal plane has a preferred orientation almost in parallel with the film surface. The manganese-based antiferromagnetic film 22 can be made of the same material as that of the manganese-based antiferromagnetic film 12 explained in [a-1].

The transition metal ferromagnetic nitride film 21 has a negative perpendicular magnetic anisotropic constant. The transition metal ferromagnetic nitride film 21 alone acts as an in-plane magnetization film whose magnetization points in an in-plane direction. The magnetization of the transition metal ferromagnetic nitride film 21 is caused to point in a direction perpendicular to the film surface forcibly by an exchange-coupling magnetic field generated by the antiferromagnetic film 22. It is desirable that exchange-coupling energy of a component of the exchange-coupling magnetic field in a direction perpendicular to the film surface should be 0.015 J/m² or more.

An embodiment of the exchange-coupling multilayer film 20 is as follows. First, a silicon substrate is introduced into a vacuum chamber. Then, the surface of the substrate is cleaned. Next, a metal target of Ta is sputtered with gaseous argon, thereby depositing a Ta film to a thickness of about 5 nm on the silicon substrate. Then, an Fe target is subjected to reactive sputtering with a gaseous mixture of argon (90 vol %) and nitrogen (10 vol %), thereby depositing an Fe—N film to a thickness of about 10 nm. Next, an alloy target with an Ir (20 at %)-Mn (80 at %) composition is sputtered with gaseous argon, thereby depositing an Ir—Mn film to a thickness of about 7 nm. Here, a method of forming a film at high temperatures in depositing an Ir—Mn film to increase an exchange-coupling magnetic field is effective.

Next, an Ru target is sputtered with gaseous argon, thereby depositing an Ru film to a thickness of about 8.5 nm, and an alloy target with a composition of Cr (80 at %) and B (20 at %) is sputtered with gaseous argon, thereby depositing a Cr—B film to a thickness of about 2.5 nm. Then after a Ta target is sputtered with gaseous argon, thereby depositing a Ta film to a thickness of about 5 nm, the specimen is taken out from the vacuum chamber into the air.

The silicon substrate on which the multilayer film has been formed is subjected to an in-magnetic-field heat treatment in a direct-current magnetic field of 1 to 2 tesla in a direction perpendicular to the film surface, thereby producing an Fe—N ferromagnetic film whose magnetization points in a direction perpendicular to the film surface. In the heat treatment condition, the applied magnetic field is set larger than the demagnetizing field of a 10-nm-thick Fe—N film.

The Fe—N film used here has stabilized phases with various compositions, including FeN, Fe₂N, and Fe₄N. It is known that any of them excluding Fe₁₆N₂ which is very difficult to crystallize is an in-plane magnetization film whose perpendicular magnetic anisotropic constant is negative.

A film using a different material and a different composition may be used for the exchange-coupling multilayer film 20 as in [a-1]. In addition, film formation conditions, a film forming method, heat treatment conditions, and the like can be varied as in [a-1].

[b] Magnetoresistive Effect Film (MTJ Element)

Any one of the two types of exchange-coupling multilayer films in [a-1] and [a-2] can be used for an MTJ element. An MTJ element using [a-1] and an MTJ element using [a-2] are called [b-1] an inversely stacked layer MTJ element and [b-2] a normally stacked layer MTJ element respectively. An inversely stacked layer MTJ element and a normally stacked layer MTJ element will be described in detail below.

[b-1] Inversely Stacked Layer MTJ Element

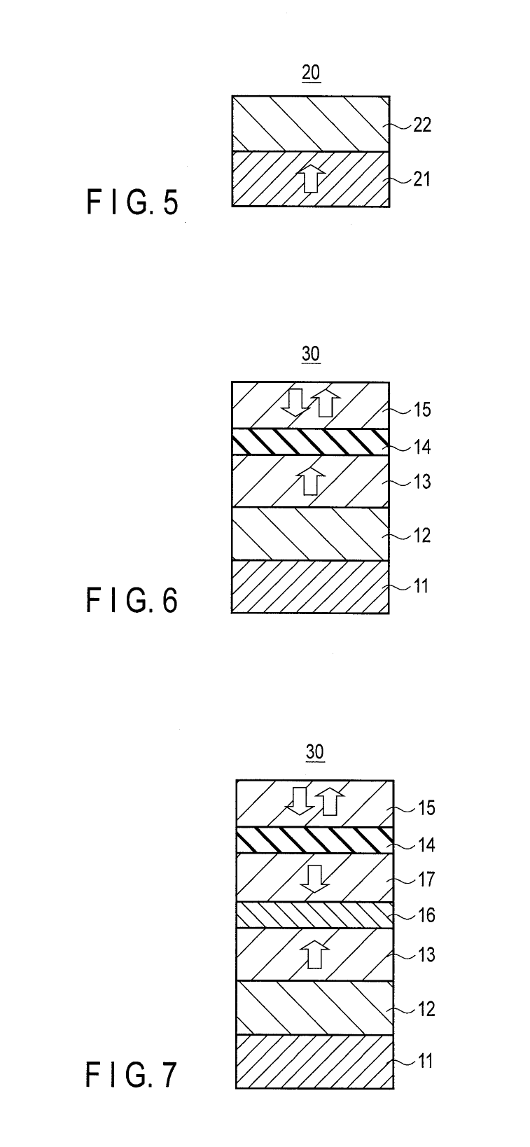

FIG. 6 is a sectional view showing a configuration of an inversely stacked layer MTJ element 30. The inversely stacked layer MTJ element 30 includes a multilayer structure obtained by stacking at least a transition metal nitride film 11, a manganese-based antiferromagnetic film 12, a ferromagnetic film (a magnetization fixed layer) 13 whose magnetization direction is fixed, a nonmagnetic film (a tunnel barrier film) 14, and a ferromagnetic film (a memory layer, a recording layer) 15 one on top of another in that order. That is, the inversely stacked layer MTJ element 30 has a top free structure where the memory layer is located above the magnetization fixed layer.

The transition metal nitride film 11, manganese-based antiferromagnetic film 12, ferromagnetic film 13 whose magnetization direction is fixed have the same configuration as that of the exchange-coupling multilayer film 10 in [a-1]. The ferromagnetic film 15 is composed of a perpendicular magnetic anisotropic film (perpendicular magnetization film) with magnetic anisotropy in a direction perpendicular to the film surface. The magnetization direction of the ferromagnetic film 15 is variable. The perpendicular magnetic anisotropic film, which is composed of a ferromagnetic film, has a positive perpendicular magnetic anisotropic constant in terms of the entire ferromagnetic film. The perpendicular magnetic anisotropic film alone acts as a perpendicular magnetization film whose magnetization points in a direction perpendicular to the film surface.

The coercive force of the magnetization fixed layer is set greater than that of the memory layer. This enables a magnetization fixed layer whose magnetization direction is fixed and a memory layer whose magnetization direction is variable to be realized with respect to a specific write current. When a write current flowing from the memory layer toward the magnetization fixed layer (in the reverse direction, in the case of electrons) is caused to flow in an MTJ element, the magnetization direction of the memory layer points in a direction parallel with the magnetization direction of the magnetization fixed layer, bringing the resistance of the MTJ element into a low resistance state, which enables binary 0 to be stored. On the other hand, when a write current flowing from the magnetization fixed layer toward the memory layer is caused to flow in the MTJ element, the magnetization direction of the memory layer points in a direction in antiparallel with the magnetization direction of the magnetization fixed layer, bringing the resistance of the MTJ element into a high resistance state, which enables binary 1 to be stored.

The inversely stacked layer MTJ element 30 can be produced in the following procedure. First, a silicon substrate is introduced into a vacuum chamber. Then, the surface of the substrate is cleaned. Next, in a similar procedure to that in [a-1] or [a-2], a multilayer film of Ta about 5 nm thick/Ru—N about 3 nm thick/Ir—Mn about 7 nm thick/Fe—B about 2 nm thick/MgO about 1 nm thick/Gd—Fe—Co about 2 nm thick/Ta about 30 nm thick is deposited by sputtering techniques. When a stacked structure is shown, the left side of “/” represents a lower layer and the right side represents an upper layer. Here, an MgO film acting as the tunnel barrier film 14 is formed by sputtering an MgO target with gaseous argon. A Gd—Fe—Co film acting as the memory layer 15 is formed by sputtering an alloy target with a composition of Gd (21 at %), Fe (47.4 at %) and Co (31.6 at %) with gaseous argon. Thereafter, the Gd—Fe—Co film is subjected to an in-magnetic-field heat treatment in a direct-current magnetic field of 1 to 2 tesla in a direction perpendicular to the film surface, thereby producing a perpendicular magnetization MTJ element where the magnetization of the Fe—B film (magnetization fixed layer 13) and that of the Gd—Fe—Co film (memory layer 15) point in a direction perpendicular to the film surface.

The reason why the Ta film serving as a protective film has a thickness of 30 nm is that the film is expected to be used as a pattern mask for microfabrication. Here, the thickness of the Fe—B film is 2 nm, one-fifth of that in the embodiment of [a-1]. Therefore, the exchange-coupling magnetic field at the inversely stacked layer MTJ element 30 this time is at about 0.5 tesla, five times 0.1 tesla. When the Gd—Fe—Co film is made as thins as 2 nm, the coercive force of the Cd—Fe—Co film is at about 0.025 tesla. Even if the Cd—Fe—Co gets thinner, the perpendicular magnetic anisotropy still remains. Therefore, the multilayer film functions as an MTJ element with no problem.

As a comparative example, a perpendicular magnetization MTJ element using a conventional perpendicular magnetic anisotropic film has a film structure of, for example, Ta about 5 nm thick/Ir about 5 nm thick/Tb—Fe—Co about 25 nm thick/MgO about 1 nm thick/Gd—Fe—Co about 2 nm thick/Ta about 30 nm thick. Here, a Tb—Fe—Co film is formed by sputtering an alloy target with a composition of Tb (20 at %), Fe (60 at %) and Co (40 at %) with gaseous argon. An Ir film, which is formed by sputtering an Ir target with gaseous krypton, is used to induce the perpendicular magnetic anisotropy of the Tb—Fe—Co film. The overall film thickness of the perpendicular magnetization MTJ element in the comparative example is as thick as about 68 nm, whereas a perpendicular magnetization MTJ element using the aforementioned exchange coupling can be made as thin as about 50 nm. A leakage magnetic field from the magnetization fixed layer is proportional to the product of the film thickness and the saturated magnetization. When a perpendicular magnetic anisotropic film is used, the leakage magnetic field is at 6 tesla·nm=0.12 Tesla×50 nm, whereas, when exchange coupling is used, the leakage magnetic field can be halved to 3 Tesla·nm=5 Tesla×2 nm.

When an MTJ element is used for an MRAM, a method of adding a third ferromagnetic film (a shift adjusting layer) via a nonmagnetic film in addition to the aforementioned structure of a first ferromagnetic film (magnetization fixed layer/tunnel barrier film/a second ferromagnetic film (memory layer) is effective in making the memory operating point zero. The reason is that the aforementioned structure permits a leakage magnetic field from the first ferromagnetic film whose magnetization direction is fixed to be applied to the second ferromagnetic film, producing an energetically stable state when the magnetization directions of both films point in a direction in parallel with each other, with the result that “0” can be written with a small current, but a large current is required to write “1.” To make the memory operating point zero, the first ferromagnetic film and the third ferromagnetic film are magnetized so that the magnetization direction of the first ferromagnetic film and that of the third ferromagnetic film may be in antiparallel with each other, thereby cancelling a leakage magnetic field from the first ferromagnetic film with a leakage magnetic field from the third ferromagnetic film. Use of this film structure makes a spin transfer current in a forward direction and that in a backward direction almost the same, which makes it easier to realize a one-cell one-transistor MRAM where a single transistor is used to drive a write current to a storage element.

FIG. 7 is a sectional view showing a configuration of an inversely stacked layer MTJ element 30 with a shift adjusting layer. The inversely stacked layer MTJ element 30 includes a multilayer structure obtained by stacking at least a transition metal nitride film 11, an antiferromagnetic film 12, a ferromagnetic film (shift adjusting layer) 13, a nonmagnetic layer (antiparallel coupling film) 16, a ferromagnetic film (magnetization fixed layer) 17, a nonmagnetic film (tunnel barrier film) 14, and a ferromagnetic film (memory layer) 15 one on top of another in that order. In the embodiment, an exchange-coupling film based on superexchange interaction can be used for the shift adjusting layer 13. The shift adjusting layer 13 reduces a leakage magnetic field from the magnetization fixed layer 17.

The MTJ element 30 has a film structure of, for example, Ta about 5 nm thick/Ru—N about 3 nm thick/Ir—Mn about 7 nm thick/Fe—B about 2 nm thick/Ru about 0.85 nm thick/Co—Fe—B about 2 nm thick/MgO about 1 nm thick/Gd—Fe—Co about 2 nm thick/Ta about 30 nm thick. An Fe—B film acts as the shift adjusting layer 13. An Ru film serving as the antiparallel coupling film 16 causes the magnetizations of adjacent ferromagnetic films to point in a direction in antiparallel with each other by superexchange interaction (Phys. Rev. B, Vol. 44, No. 13, pp. 7131). It is known that not only Ru but also Ir, Rh, or the like produces strong superexchange interaction in the antiparallel coupling film 16. Antiparallel exchange-coupling energy is at 0.16 to 0.5 J/m² (Phys. Rev. Lett., Vol. 67, No. 25, pp. 3598). In the embodiment, the antiparallel coupling film 16 includes any one selected from a group consisting of Ru, Ir, and Rh, or an alloy comprising two or more selected from the group. In addition, it is desirable that the exchange-coupling energy of an antiparallel exchange-coupling magnetic field via an antiparallel coupling film should be 0.15 J/m² or more.

A Co—Fe—B film acting as the magnetization fixed layer 17 is formed by sputtering an alloy target with a composition of Co (40 at %), Fe (40 at %) and B (20 at %) with gaseous argon. The Co—Fe—B film functions as an underlying film for an MgO film serving as the tunnel barrier film 14. The Co—Fe—B film and Fe—B film have almost the same saturated magnetization. An antiparallel exchange-coupling magnetic field generated via the Ru film is at about 0.7 Tesla less than that of a demagnetizing field of a Fe—B single film or a Co—Fe—B single film. When the magnetization of the Fe—B film and that of the Co—Fe—B film have pointed in a direction in antiparallel with each other, both demagnetizing fields cancel each other, enabling antiparallel coupling to be kept with no problem. Although perpendicular magnetic anisotropic films can be exchange-coupled with each other via the Ru film, complete antiparallel coupling cannot be obtained because an anisotropic magnetic field of the perpendicular magnetic anisotropic film is almost as strong as an exchange-coupling magnetic field generated via the Ru film.

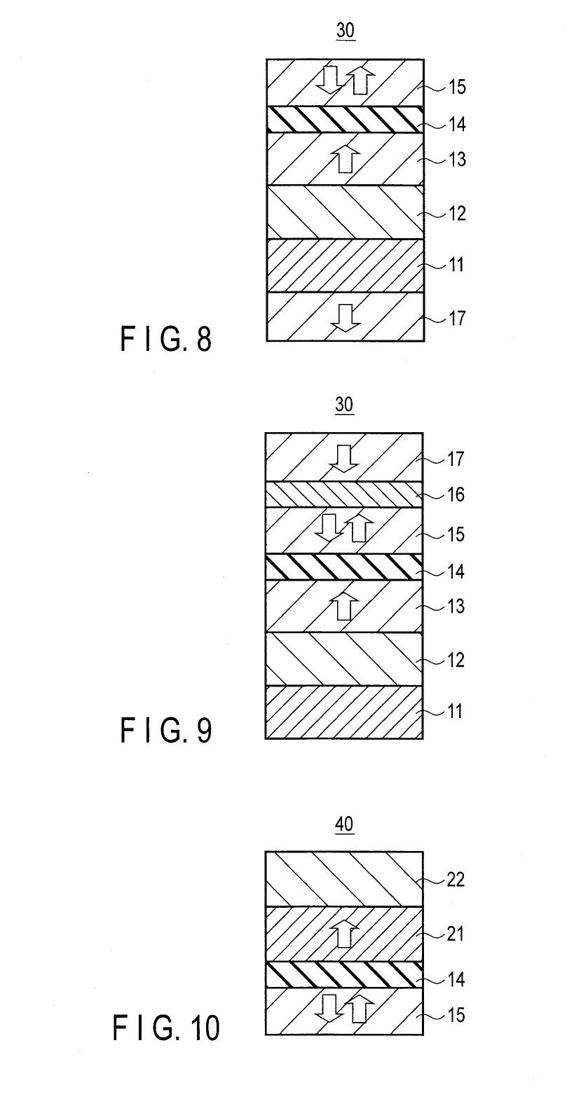

In the case of a material configuration that cannot use the superexchange interaction, a perpendicular magnetic anisotropic film can be used as a third ferromagnetic film (shift adjusting layer). FIG. 8 is a sectional view showing a configuration of an inversely stacked layer MTJ element 30 according to a first modification. The inversely stacked layer MTJ element 30 of the first modification includes a multilayer structure obtained by stacking at least a ferromagnetic film (shift adjusting layer) 17, a transition metal nitride film 11, an antiferromagnetic film 12, a ferromagnetic film (magnetization fixed layer) 13, a nonmagnetic film (tunnel barrier film) 14, and a ferromagnetic film (memory layer) 15 one on top of another in that order. In the first modification, the shift adjusting layer 17 composed of a perpendicular magnetic anisotropic film is placed under the transition metal nitride film 11. The magnetization direction of the shift adjusting layer 17 and that of the magnetization fixed layer 13 are set in antiparallel with each other.

The first modification has a film structure of, for example, Ta about 5 nm thick/Ir about 5 nm thick/Tb—Fe—Co about 40 nm thick/Ru—N about 3 nm thick/Ir—Mn about 7 nm thick/Fe—B about 1 nm thick/Co—Fe—B about 1 nm thick/MgO about 1 nm thick/Gd—Fe—Co about 2 nm thick/Ta about 30 nm thick. A Tb—Fe—Co film acts as the shift adjusting layer 17, an Fe—B film and a Co—Fe—B film act as the magnetization fixed layer 13, and a Gd—Fe—Co film acts as the memory layer 15.

FIG. 9 is a sectional view showing a configuration of an inversely stacked layer MTJ element 30 according to a second modification. The inversely stacked layer MTJ element 30 of the second modification includes a multilayer structure obtained by stacking at least a transition metal nitride film 11, an antiferromagnetic film 12, a ferromagnetic film (magnetization fixed layer) 13, a nonmagnetic film (tunnel barrier film) 14, a ferromagnetic film (memory layer) 15, a nonmagnetic film (antiparallel coupling film) 16, and a ferromagnetic film (shift adjusting layer) 17 one on top of another in that order. In the second modification, the shift adjusting layer 17 composed of a perpendicular magnetic anisotropic film is placed above the memory layer 15 via the antiparallel coupling film 16. The magnetization direction of the shift adjusting layer 17 and that of the magnetization fixed layer 13 are set in antiparallel with each other.

The second modification has a film structure of, for example, Ta about 5 nm thick/Ru—N about 3 nm thick/Ir—Mn about 7 nm thick/Fe—B about 1 nm thick/Co—Fe—B about 1 nm thick/Mg—O about 1 nm thick/Gd—Fe—Co about 2 nm thick/Ir about 5 nm thick/Tb—Fe—Co about 25 nm thick/Ta about 30 nm thick. A Fe—B film and a Co—Fe—B film act as the magnetization fixed layer 13, a Gd—Fe—Co film acts as the memory layer 15, and a Tb—Fe—Co film acts as the shift adjusting layer 17.

The reason why the Tb—Fe—Co film (shift adjusting layer 17) of the second modification is thinner than that of the first modification is that the Tb—Fe—Co film is closer to the memory layer 15 and a more part of a leakage magnetic field is applied to the film, with the result that, even if the film is thinner by just that much, the operating point can be secured. In the case of the film structures of the first modification and second modification, after an in-magnetic-field heat treatment has been performed following the film formation, the films are magnetized by applying a direct-current magnetic field not less than the coercive force of the Tb—Fe—Co film in a direction opposite to the applied magnetic field in heat treatment at room temperature, which enables the state of a zero operating point to be produced.

On the other hand, a structure obtained by adding a third ferromagnetic film (shift adjusting layer) to a perpendicular magnetization MTJ element using a perpendicular magnetic anisotropic film of a comparative example is of, for example, Ta about 5 nm thick/Ir about 5 nm thick/Dy—Fe—Co about 40 nm thick/Ir about 3 nm thick/Tb—Fe—Co about 25 nm thick/MgO about 1 nm thick/Gd—Fe—Co about 2 nm thick/Ta about 30 nm thick. Here, a Dy—Fe—Co film is formed by sputtering an alloy target with a composition of Dy (20 at %), Fe (60 at %) and Co (40 at %) with gaseous argon. The overall film thickness of the perpendicular magnetization MTJ element is about 111 nm, whereas a perpendicular magnetization MTJ element using the aforementioned superexchange interaction becomes thinner remarkably to about 53 nm.

In a perpendicular magnetization MTJ element with only a perpendicular magnetic anisotropic film, a magnetizing process for cancelling a leakage magnetic field is more difficult than in a film using exchange coupling. In the comparative example, if the coercive force of the Dy—Fe—Co film is at about 2.4 Tesla, first the film is magnetized in a direction at 2.4 Tesla. Next, if the coercive force of the Tb—Fe—Co film is at about 2 Tesla, it is necessary to magnetize the film reversely at 2 to 2.4 Tesla in a direction in antiparallel with 2.4-Tesla magnetizing process. The coercive forces of these films are such that, when the size of an MTJ element is several tens of nanometers, if, for example, a variation of 1 nm in the size results in a variation of 0.2 Tesla. Therefore, when 2.2 Tesla has been applied to magnetize the Tb—Fe—Co film in a direction in antiparallel, the following variation takes place: the Dy—Fe—Co film might be reversely magnetized or the Tb—Fe—Co film might not be reversely magnetized. In contrast, in an exchange-coupling multilayer film using superexchange interaction, the magnetizations of two layers of ferromagnetic films always point in a direction in antiparallel even when the films are not reversely magnetized, enabling a magnetization fixed state without a variation in the magnetization direction to be realized.

While in the above example, a Gd—Fe—Co film has been used as the perpendicular magnetic anisotropic film of the memory layer 15, another perpendicular magnetic anisotropic film, for example, the aforementioned cobalt-platinum (Co—Pt)-based alloy, an iron-palladium (Fe—Pd)-based alloy, an iron-platinum (Fe—Pt)-based alloy, a Co/Pd or Co/Pt artificial lattice, or the like, may be used. These may be formed by not only the sputtering of an alloy target but also a simultaneous sputtering of two types of targets, a film formation method other than the sputtering methods, a vacuum vapor deposition method, a molecular beam epitaxial method, a CVD method, or the like.

In addition, while a method of sputtering an MgO target with gaseous argon has been explained as an example of the method of forming an MgO film, a method of sputtering an MgO target with a gaseous mixture of argon and oxygen, a method of sputtering an Mg target with a gaseous mixture of argon and oxygen, a method of forming a film by sputtering an Mg target with gaseous argon and exposing the film to gaseous oxygen to oxidize the surface of the Mg target, thereby forming an MgO film, may be used. In addition, an MgO film may be formed by not only the sputtering method but also a vacuum vapor deposition method, a molecular beam epitaxial method, a CVD method, or the like.

Furthermore, while in the above example, an MgO film has been used as the tunnel barrier film 14, the MgO film may be replaced with another material that produces a TMR effect, for example, Al—O, oxidized titanium, aluminium nitride, or the like. Furthermore, the MgO film may be used not as an insulating film but as a spin valve film instead of a nonmagnetic conducting film of Cu or Pd.

[b-2] Normally Stacked Layer MTJ Element

FIG. 10 is a sectional view showing a configuration of a normally stacked layer MTJ element 40. The normally stacked layer MTJ element 40 includes a multilayer structure obtained by stacking at least a ferromagnetic film (memory layer) 15, a nonmagnetic film (tunnel barrier film) 14, a transition metal ferromagnetic nitride film (magnetization fixed layer) 21, and a manganese-based antiferromagnetic film 22 one on top of another in that order. That is, the normally stacked layer MTJ element 40 has a bottom free structure where the memory layer is located below the magnetization fixed layer.

The transition metal ferromagnetic nitride film 21 and manganese-based antiferromagnetic film 22 have the same configuration as that of the second exchange-coupling multilayer film 20 in [a-2]. The ferromagnetic film 15 is composed of a perpendicular magnetic anisotropic film (perpendicular magnetization film) with magnetic anisotropy in a direction perpendicular to the film surface.

The normally stacked layer MTJ element 40 can be produced in the following procedure. First, a silicon substrate is introduced into a vacuum chamber. Then, the surface of the substrate is cleaned. Next, in a similar procedure to that in [a-1], [a-2], or [b-1], a multilayer film of Ta about 5 nm thick/Gd—Fe—Co about 2 nm thick/MgO about 1 nm thick/Fe—N about 2 nm thick/Ir—Mn about 7 nm thick/Ta about 30 nm thick is deposited by sputtering techniques. Then, the multilayer film is subjected to an in-magnetic-field heat treatment in a direct-current magnetic field of 1 to 2 tesla in a direction perpendicular to the film surface, thereby producing a perpendicular magnetization MTJ element where the magnetization of the Fe—N film and that of the Gd—Fe—Co film point in a direction perpendicular to the film surface.

The overall film thickness of the multilayer film can be made as thin as about 47 nm. A leakage magnetic field from the magnetization fixed layer is suppressed to 4 tesla·nm=2 tesla×2 nm. In calculating the saturated magnetization, 2 tesla of Fe₄N, the largest in the Fe—N series, was used.

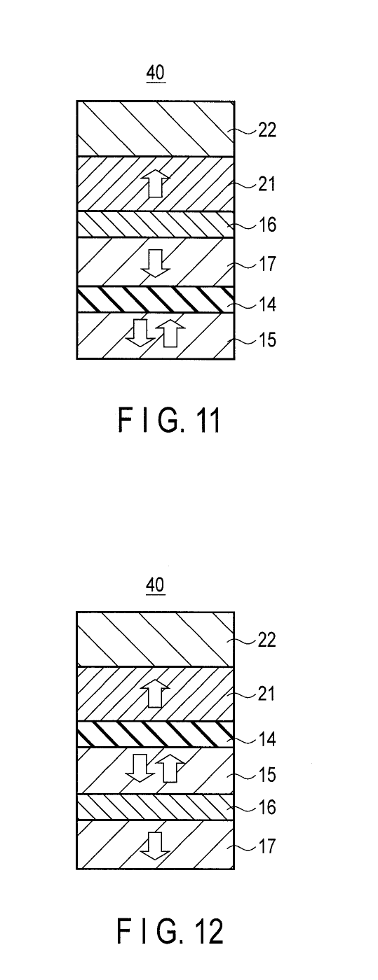

In the normally stacked layer MTJ element 40, too, a third ferromagnetic film (shift adjusting layer) for making the memory operating point zero may be added. FIG. 11 is a sectional view showing a configuration of a normally stacked layer MTJ element 40 with a shift adjusting layer. The normally stacked layer MTJ element 40 includes a multilayer structure obtained by stacking at least a ferromagnetic film (memory layer) 15, a nonmagnetic film (tunnel barrier film) 14, a ferromagnetic film (magnetization fixed layer) 17, a nonmagnetic layer (antiparallel coupling film) 16, a transition metal ferromagnetic nitride film (shift adjusting layer) 21, and an antiferromagnetic film 22 one on top of another in that order. The magnetization direction of the ferromagnetic film (magnetization fixed layer) 17 and that of the transition metal ferromagnetic nitride film (shift adjusting layer) 21 are fixed in antiparallel via the antiparallel coupling film 16 by superexchange interaction.

The normally stacked layer MTJ element 40 has a film structure of, for example, Ta about 5 nm thick/Gd—Fe—Co about 2 nm thick/MgO about 1 nm thick/Co—Fe—B about 2.7 nm thick/Ru about 0.85 nm thick/Fe—N about 2 nm thick/Ir—Mn about 7 nm thick/Ta about 30 nm thick. A Gd—Fe—Co film acts as the memory layer 15, a Co—Fe—B film acts as the magnetization fixed layer 17, and an Fe—N film acts as the shift adjusting layer 21. Not only Ru but also Cr, Ir, or Rh may be used as the antiparallel coupling film 16. The magnetization of the Co—Fe—B film is in antiparallel with that of the Fe—N film. Since the saturated magnetization of the Co—Fe—B film is smaller than that of the Fe—N film, the Co—Fe—B film is made thicker than the Fe—N film so as to cancel a leakage magnetic field.

In the case of a material configuration that cannot use the superexchange interaction, a perpendicular magnetic anisotropic film can be used as a third ferromagnetic film (shift adjusting layer).

FIG. 12 is a sectional view showing a configuration of a normally stacked layer MTJ element 40 according to a first modification. The normally stacked layer MTJ element 40 of the first modification includes a multilayer structure obtained by stacking at least a ferromagnetic film (shift adjusting layer) 17, a nonmagnetic film (antiparallel coupling film) 16, a ferromagnetic film (memory layer) 15, a nonmagnetic film (tunnel barrier film) 14, a transition metal ferromagnetic nitride film (magnetization fixed layer) 21, and an antiferromagnetic film 22 one on top of another in that order. In the first modification, the shift adjusting layer 17 composed of a perpendicular magnetic anisotropic film is located below the memory layer 15. The magnetization direction of the shift adjusting layer 17 and that of the magnetization fixed layer 21 are set in antiparallel with each other.

The normally stacked layer MTJ element 40 of the first modification has a film structure of, for example, Ta about 5 nm thick/Ir about 5 nm thick/Tb—Fe—Co about 25 nm thick/Ir about 5 nm thick/Gd—Fe—Co about 2 nm thick/MgO about 1 nm thick/Co—Fe—B about 1 nm thick/Fe—N about 1 nm thick/Ir—Mn about 7 nm/Ta about 30 nm. A Tb—Fe—Co film acts as the shift adjusting layer 17, a Gd—Fe—Co film acts as the memory layer 15, and a Co—Fe—B film and an Fe—N film act as the magnetization fixed layer 21. An Ir film is used as an underlying film for strengthening the perpendicular magnetic anisotropy of the Gd—Fe—Co film or the like.

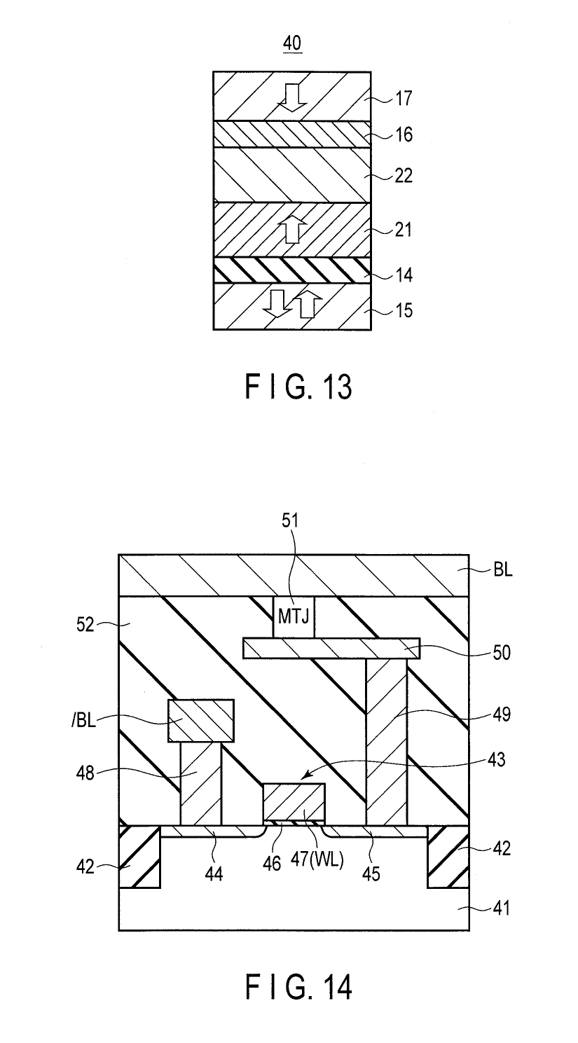

FIG. 13 is a sectional view showing a configuration of a normally stacked layer MTJ element 40 according to a second modification. The normally stacked layer MTJ element 40 of the second modification includes a multilayer structure obtained by stacking at least a ferromagnetic film (memory layer) 15, a nonmagnetic film (tunnel barrier film) 14, a transition metal ferromagnetic nitride film (magnetization fixed layer) 21, an antiferromagnetic film 22, a nonmagnetic film (antiparallel coupling film) 16, and a ferromagnetic film (shift adjusting layer) 17 one on top of another in that order. In the second modification, the shift adjusting layer 17 composed of a perpendicular magnetic anisotropic film is located above the antiferromagnetic film 22. The magnetization direction of the shift adjusting layer 17 and that of the magnetization fixed layer 21 are set in antiparallel with each other.

The normally stacked layer MTJ element 40 of the second modification has a film structure of, for example, Ta about 5 nm thick/Ir about 5 nm thick/Gb—Fe—Co about 2 nm thick/MgO about 1 nm thick/Gd—Fe—B about 1 nm thick/Fe—N about 1 nm thick/Ir—Mn about 7 nm thick/Ir about 5 nm thick/Tb—Fe—Co about 35 nm/Ta about 30 nm. A Gd—Fe—Co film acts as the memory layer 15, a Co—Fe—B film and an Fe—N film act as the magnetization fixed layer 21, and a Tb—Fe—Co film acts as the shift adjusting layer 17.

The reason why the Gd—Fe—Co film (shift adjusting layer 17) of the first modification is thinner than that of the second modification is the same as in [b-1]. The overall film thicknesses of the multilayer films of the first and second modifications are at about 82 nm and 92 nm, respectively. Therefore, the multilayer films of the first and second modifications can be made thinner than the multilayer film of 111 nm thick composed of only a perpendicular magnetic anisotropic film shown in [b-1].

[c] MRAM

Next, an embodiment when an MRAM is configured using an MTJ element explained in [b] will be explained. FIG. 14 is a sectional view showing a configuration of an MRAM.

In a p-type semiconductor substrate 41, an element isolation insulating layer 42 with a shallow trench isolation (STI) structure is provided. In an element region (active region) surrounded by the element isolation insulating layer 42, an n-channel MOSFET acting as a select transistor 43 is provided. The select transistor 43 includes a source region 44 and a drain region 45 formed separately in the element region, a gate insulating film 46 provided on a channel region between the source region 44 and drain region 45, and a gate electrode 47 provided on the gate insulating film 46. The gate electrode 47 corresponds to a word line WL. Each of the source region 44 and drain region 45 is composed of an n-type diffused region.

On the source region 44, there is provided a contact plug 48. On the contact plug 48, a bit line/BL is provided. On the drain region 45, a contact plug 49 is provided. On the contact plug 49, an extraction electrode 50 is provided. On the extraction electrode 50, there is provided a storage element 51. Any one of the MTJ elements explained in [b] can be used as the storage element 51. On the storage element 51, a bit line BL is provided. A space between the semiconductor substrate 41 and bit line BL is filled with an interlayer insulating layer 52. Actually, the MRAM includes a memory cell array in which a plurality of units of the memory cell (composed of a select transistor 43 and a storage element 51) shown in FIG. 14 are arranged in a matrix.

(Manufacturing Method)

Next, a method of manufacturing an MRAM using an MTJ element in [b] will be explained. An inversely stacked layer MTJ element in [b-1] and a normally stacked layer MTJ element in [b-2] are the same in the manufacturing processes excluding the configuration of a multilayer film and therefore a case where an inversely stacked layer. MTJ element in [b-1] has been basically used will be illustrated hereinafter.

In the formation of an MRAM, first, a drive transistor that generates a spin transfer current, a select transistor that selects a bit to be written/read, a peripheral transistor that shapes a read signal, a transistor that supplies power to these transistors, metal wiring lines to storage elements, wiring lines that connect transistors with one another, and the like are formed on a silicon substrate. These elements and wiring lines are formed by a general manufacturing method.

Next, an MTJ element is formed in the procedure as shown in [b-1] and subjected to an in-magnetic-field heat treatment. When superexchange interaction is used, the process just proceeds to the next one. When a perpendicular magnetic anisotropic film is used, the MTJ element is magnetized once and then the process proceeds to the next one.

Next, on the MTJ element, for example, a silicon oxide (Si—O) film is deposited as a dummy mask to a thickness of about 30 nm by CVD techniques. Then, on the Si—O film, a 60-nm-diameter dot resist pattern is formed by a resist process. With this resist pattern as a mask, the dot pattern is transferred to the Si—O film by RIE using gaseous CHF₃. The reason why the Si—O film is used as a dummy mask is that the selected ratio of the resist to a Ta film is low in a subsequent Ta-film RIE process and therefore it is necessary to use an Si—O film that has a high selected ratio with respect to a Ta film.

Next, with the Si—O film pattern as a mask, the dot pattern is transferred to a 30-nm-thick Ta film by RIE using gaseous CF₄. At this time, the Si—O mask has disappeared completely. Then, with the Ta film pattern as a mask, the MTJ element is microfabricated as far as the bottom Ta film by IBE using an Ar ion beam. Since the overall film thickness of the MTJ element is as thin as about 53 nm, processing can be performed to achieve a minimum distance of 60 nm between dots. Immediately after this process, the cross section of the MTJ element is exposed. If the MTJ element is taken out into the air as it is, the interface of the exchange-coupling part will be oxidized and the exchange-coupling magnetic field will decrease. Therefore, it is best to form a sidewall protective film continuously in a vacuum after the IBS process. Here, as a sidewall protective film, a silicon nitride (Si—N) film is deposited to a thickness of about 10 nm by CVD techniques. The reason why CVD techniques are used is that the silicon nitride film adheres to the sidewall suitably.

Next, to cover a step of about 50 nm thick caused in microfabrication, an Si—O film is deposited to a thickness of about 70 nm by CVD techniques. Since the Si—O film sticks uniformly to the trench portion resulting from removal by IBE and the remaining MTJ dot portion, the Si—O film projects from the dot portion at the substrate surface after the Si—O film formation. To eliminate the roughness (irregularities), the Si—O film and Si—N film are ground and planarized by a chemical mechanical polishing (CMP) method until the top Ta film of the MTJ dot has been exposed. The reason why an Si—O film is used to cover the step in spite of using an Si—N film as a sidewall protective film is that it is difficult to apply CMP to an Si—N film and therefore the Si—N film is not planarized and that an Si—O film easy to be planarized is used to cover the step. On the other hand, the reason why an Si—O film is not used as a sidewall protective film is that the sidewall of the MTJ dot is oxidized when a film is formed by CVD techniques.

Next, the MTJ element with dots composed of parts of the Ta film and Si—N film being exposed at the surface of the Si—O film is introduced into a vacuum chamber. After the surface of the MTJ element is cleaned, a titanium film is deposited to a thickness of about 5 nm on the entire surface of the element. Then, a tungsten film is deposited to a thickness of about 100 nm by CVD techniques. After that, a resist pattern for an upper electrode is formed in a resist process. With the resist pattern as a mask, the tungsten and titanium are removed by RIE using gaseous CF₄. The trench part resulting from removal by RIE is filled with an Si—O film by CVD techniques and the surface is planarized by CMP techniques. Thereafter, the remaining wiring lines are formed, thereby completing an MRAM.

The MRAM forming process shown here complies with almost a basic semiconductor process excluding the process of microfabricating an MTJ element by IBE.

[d] Example of a Manufacturing Apparatus

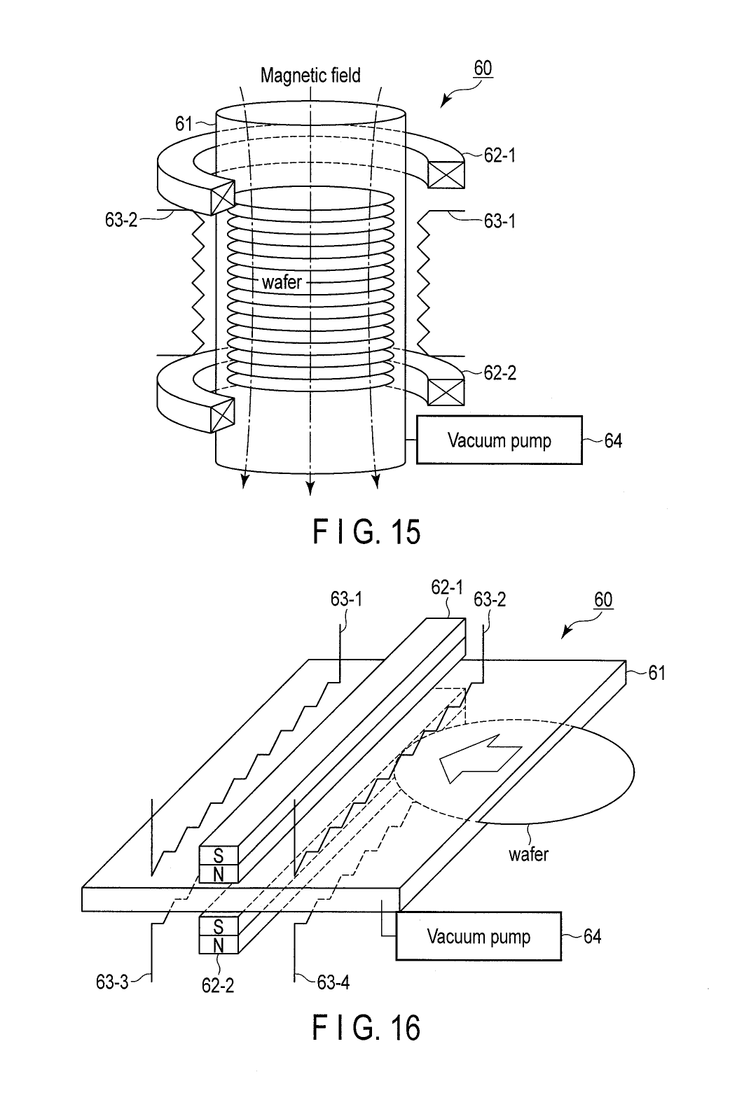

Next, an example of a manufacturing apparatus for manufacturing an MTJ element will be explained. FIG. 15 is a schematic diagram of a magnetizing apparatus 60. The magnetizing apparatus 60 comprises a heat-treating furnace 61, coils 62-1, 62-2, heaters 63-1, 63-2, and a vacuum pump 64.

The heat-treating furnace 61 is a batch heat-treating furnace that can process a plurality of wafers at the same time. In the heat-treating furnace 61, a plurality of wafers to be magnetized are placed. At each wafer, a plurality of MTJ elements of the embodiment have been formed.

On the lateral face side of the heat-treating furnace 61, the heaters 63-1, 63-2 that apply heat to the heat-treating furnace 61 are arranged. The heaters 63-1, 63-2 are located in, for example, the central part of the heat-treating furnace 61. Further on the lateral face side of the heat-treating furnace 61, the coils 62-1, 62-2 for applying a magnetic field to the wafers in the heat-treating furnace 61 are arranged. The coils 62-1, 62-2 are provided in the upper part and the lower part of the heat-treating furnace 61, respectively. For example, superconducting coils are used as the coils 62-1, 62-2. The vacuum pump 64 is connected to the heat-treating furnace 61. The vacuum pump 64 forms a vacuum in the heat-treating furnace 61 during a magnetizing process.

With the magnetizing apparatus 60 configured as described above, a vertical direct-current magnetic field can be applied to the wafers (MTJ elements), while the wafers are being heat-treated in a vacuum. Each condition (the magnitude of a magnetic field, temperature, or time) in the magnetizing process is set according to the embodiment. Depending on the position where a wafer is located and a partial region of the wafer (particularly an edge portion of the wafer), a magnetic field might be applied to the wafer so as to be inclined a little from a vertical direction without being applied to the wafer vertically. However, the magnetic field is allowed to be inclined a little from a vertical direction, provided that the magnetized MTJ elements have a desired magnetic characteristic. For example, if the direction in which the magnetic field is applied is within ±5° with respect to the vertical direction, the inclination of the magnetic field is accepted.

FIG. 16 is a schematic diagram showing another configuration of the magnetizing apparatus 60. The magnetizing apparatus 60 comprises a heat-treating furnace 61, permanent magnets 62-1, 62-2, heaters 63-1, 63-4, and a vacuum pump 64.

The heat-treating furnace 61 is a sheet-feed heat-treating furnace that processes wafers one by one. Wafers to be magnetized are transported one by one sequentially into the heat-treating furnace 61. The permanent magnets 62-1, 62-2 are arranged above and below the heat-treating furnace 61, respectively. The heaters 63-1, 63-2 are arranged on both sides of the permanent magnet 62-1 above the heat-treating furnace 61. The heaters 63-3, 63-4 are arranged on both sides of the permanent magnet 62-2 below the heat-treating furnace 61. The vacuum pump 64 is connected to the heat-treating furnace 61. Even when the magnetizing apparatus 60 of FIG. 16 is used, a vertical direct-current magnetic field can be applied to the wafers (MTJ elements), while the wafers are being heat-treated in a vacuum.

[e] Effects

As described above in detail, with the embodiment, the overall film thickness of a perpendicular magnetization MTJ element can be made much thinner by improving the multilayer film structure of a perpendicular magnetization MTJ element and applying a film material suitable for the improvement. This makes it possible to microfabricate an MTJ element to a minute size equal to or smaller than the thin film formation limit of a perpendicular magnetic anisotropic film. Specifically, a ferromagnetic film whose magnetization is fixed can be thinned to a thickness of about 2 nm, enabling the overall film thickness of perpendicular magnetization MTJ element including an underlying film and a protective film to be reduced to at least 53 nm or less. This enables an MRAM storage element to be microfabricated to a size of at least 60 nm or less, making it possible to cope with higher integration.

In the embodiment, the stacked structure of a multilayer film and the magnetization direction of a ferromagnetic film have been defined. Of them, the stacked structure can be identified by a structural analysis using a transmission electron microscope (TEM), an energy dispersive X-ray fluorescence spectrometer (EDX), and an electron energy-loss spectroscopy (EELS), or the like.

As for the magnetic structure, it is difficult to directly measure the magnetization direction of a magnetization fixed layer. If it has been confirmed in the structural analysis that the structure and composition of the memory layer paired with the magnetization fixed layer are those of a perpendicular magnetic anisotropic film, it is conceivable that the magnetization direction of the magnetization fixed layer is also fixed in a direction perpendicular to the film surface. The reason is that, even if the magnetization of the memory layer has been reversed in a direction perpendicular to the film surface with the magnetization direction of the magnetization fixed layer being fixed in an in-plane direction, a change in the resistance is zero in a magnetoresistive effect element. In other words, when the memory layer is composed of a perpendicular magnetic anisotropic film, if the magnetization of the magnetization fixed layer does not point in a direction perpendicular to the film surface, the magnetoresistive effect film is useless.

In recent years, a structure where a change in the state of electrons at the interface of a multilayer film induces perpendicular magnetic anisotropy in a ferromagnetic film has been found. For example, it has been reported that perpendicular magnetic anisotropy has been obtained with a stacked structure of Ta/Co—Fe—B/MgO. In this case, although a Co—Fe—B film has been magnetized in a direction perpendicular to the film surface, the Co—Fe—B film is not in contact with an antiferromagnetic film. Therefore, the development of perpendicular magnetization is not caused by an exchange-coupling magnetic field. An interface electron state theory has described that, when the p_{z} orbit of oxygen atoms in MgO and the d_{z2} orbit of Co atoms have formed a hybrid orbit, the energy decreases, the orbit angular momentum points in a direction perpendicular to the film surface, and the spin angular momentum coupled with this also points in a direction perpendicular to the film surface, thereby developing perpendicular magnetic anisotropy.

However, the perpendicular magnetic anisotropic energy of this film is very much lower than exchange-coupling energy using the aforementioned Co—Pt-based alloy, RE-TM-based perpendicular magnetic anisotropic film, or the antiferromagnetic film of the embodiment. In addition, if the Co—Fe—B film of the example is not adjacent to an oxide film, it is an in-plane magnetization film with a negative perpendicular magnetic anisotropic constant. If the Co—Fe—B film is made adjacent to an MgO film, it has a positive perpendicular magnetic anisotropic constant. Therefore, when the structure of the memory layer is analyzed, a determination must be made, depending on whether perpendicular magnetic anisotropy has developed at a stacked structure of a Co—Fe—B film and an MgO film corresponding to a memory layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive effect element comprising:
a multilayer film including a transition metal nitride film, an antiferromagnetic film, a first ferromagnetic film, a nonmagnetic film, and a perpendicular magnetic anisotropic film stacked in that order,
wherein the first ferromagnetic film has a negative perpendicular magnetic anisotropic constant, and
magnetization of the first ferromagnetic film is caused to point in a direction perpendicular to the film surface forcibly by an exchange-coupling magnetic field generated by the antiferromagnetic film.

2. The magnetoresistive effect element of claim 1, further comprising:
an antiparallel coupling film and a second ferromagnetic film stacked in that order between the first ferromagnetic film and the nonmagnetic film,
wherein the magnetization of the first ferromagnetic film and magnetization of the second ferromagnetic film are set antiparallel by superexchange interaction induced by the antiparallel coupling film.

3. The magnetoresistive effect element of claim 1, wherein the transition metal nitride film includes one selected from a group consisting of titanium nitride, vanadium nitride, chromium nitride, manganese nitride, iron nitride, cobalt nitride, copper nitride, ruthenium nitride, and tungsten nitride, or alloy nitride comprising two or more selected from the group.

4. The magnetoresistive effect element of claim 1, wherein
the transition metal nitride film has a cubic crystal structure,
a lattice constant of the transition metal nitride film is in a range of 0.379 to 0.422 nm, and
a (001) crystal plane of the transition metal nitride film is preferentially oriented almost in parallel with the film surface.

5. The magnetoresistive effect element of claim 1, wherein
the transition metal nitride film has a tetragonal crystal structure,
a lattice constant of the transition metal nitride film in a shorter direction is in a range of 0.379 to 0.422 nm, and
a (001) crystal plane of the transition metal nitride film is preferentially oriented almost in parallel with the film surface.

6. The magnetoresistive effect element of claim 1, wherein the antiferromagnetic film includes one alloy selected from a group consisting of nickel-manganese, palladium-manganese, platinum-manganese, iridium-manganese, rhodium-manganese, and ruthenium-manganese, or an alloy comprising two or more selected from the group.

7. The magnetoresistive effect element of claim 1, wherein a (001) crystal plane of the antiferromagnetic film is preferentially oriented almost in parallel with the film surface.

8. The magnetoresistive effect element of claim 1, wherein exchange-coupling energy of a component in a direction perpendicular to the film surface of the exchange-coupling magnetic field is 0.015 J/m² or more.

9. The magnetoresistive effect element of claim 2, wherein the antiparallel coupling film includes one selected from a group consisting of ruthenium, iridium, and rhodium, or an alloy comprising two or more selected from the group.

10. A magnetoresistive effect element comprising:
a multilayer film including a perpendicular magnetic anisotropic film, a nonmagnetic film, a transition metal magnetic nitride film, and an antiferromagnetic film stacked in that order,
wherein the transition metal magnetic nitride film has a negative perpendicular magnetic anisotropic constant, and
magnetization of the transition metal magnetic nitride film is caused to point in a direction perpendicular to the film surface forcibly by an exchange-coupling magnetic field generated by the antiferromagnetic film.

11. The magnetoresistive effect element of claim 10, further comprising:
a ferromagnetic film and an antiparallel coupling film stacked in sequence between the nonmagnetic film and the transition metal magnetic nitride film,
wherein magnetization of the ferromagnetic film and the magnetization of the transition metal magnetic nitride film are set antiparallel by superexchange interaction induced by the antiparallel coupling film.

12. The magnetoresistive effect element of claim 10, wherein the transition metal magnetic nitride film includes one selected from a group consisting of manganese nitride, iron nitride, and cobalt nitride, or alloy nitride comprising two or more selected from the group.

13. The magnetoresistive effect element of claim 10, wherein
the transition metal magnetic nitride film has a cubic crystal structure,
a lattice constant of the transition metal magnetic nitride film is in a range of 0.379 to 0.387 nm, and
a (001) crystal plane of the transition metal magnetic nitride film is preferentially oriented almost in parallel with the film surface.

14. The magnetoresistive effect element of claim 10, wherein
the transition metal magnetic nitride film has a tetragonal crystal structure,
a lattice constant of the transition metal magnetic nitride film in a shorter direction is in a range of 0.379 to 0.387 nm, and
a (001) crystal plane of the transition metal magnetic nitride film is preferentially oriented almost in parallel with the film surface.

15. The magnetoresistive effect element of claim 10, wherein the antiferromagnetic film includes one alloy selected from a group consisting of nickel-manganese, palladium-manganese, platinum-manganese, iridium-manganese, rhodium-manganese, and ruthenium-manganese, or an alloy comprising two or more selected from the group.

16. The magnetoresistive effect element of claim 10, wherein a (001) crystal plane of the antiferromagnetic film is preferentially oriented almost in parallel with the film surface.

17. The magnetoresistive effect element of claim 10, wherein exchange-coupling energy of a component in a direction perpendicular to the film surface of the exchange-coupling magnetic field is 0.015 J/m² or more.

18. The magnetoresistive effect element of claim 11, wherein the antiparallel coupling film includes one selected from a group consisting of ruthenium, iridium, and rhodium, or an alloy comprising two or more selected from the group.

19. A manufacturing method of a magnetoresistive effect element, the method comprising:
forming a multilayer film including a transition metal nitride film, an antiferromagnetic film, a first ferromagnetic film, a nonmagnetic film, and a perpendicular magnetic anisotropic film stacked in that order, the first ferromagnetic film having a negative perpendicular magnetic anisotropic constant; and
performing heat treatment with a magnetic field in a direction perpendicular to the film surface being applied to the multilayer film.

20. The method of claim 19, wherein the magnetic field is larger than a demagnetizing field of first ferromagnetic film.
